(19) United States
(12) Patent Application Publication
(10) Pub. No.: US 2017/0005093 A1
(43) Pub. Date: Jan. 5, 2017

(54) Semiconductor Device with Split Work Functions

(71) Applicant: Broadcom Corporation, Irvine, CA (US)

(72) Inventors: Qintao ZHANG, Tustin, CA (US); Mei XUE, Irvine, CA (US); Wenwei YANG, Lake Forest, CA (US); Akira ITO, Irvine, CA (US)

(73) Assignee: Broadcom Corporation, Irvine, CA (US)

(21) Appl. No.: 14/788,215

(22) Filed: Jun. 30, 2015

(51) Int. Cl. H01L 27/092; H01L 29/49; H01L 29/66; H01L 29/78

(52) U.S. Cl. CPC H01L 27/0922; H01L 29/7835; H01L 29/4966; H01L 29/66545

(57) ABSTRACT

A field effect transistor (FET) configuration is provided having a gate region with a split work function for the source-side and drain-side of the gate region. The work function of a material is defined as the minimum energy required to extract an electron from the surface of the material to free space. Accordingly, the source-side portion of the gate region has a first work function that less than a second work function of the drain-side portion, the result of which is increased breakdown voltage at the drain-gate interface, without significantly increasing the threshold voltage of the FET. The split work function is achieved by layering n-type gate material over p-type gate material in the drain-side portion of the gate region, while only the n-type gate material us used in the source-side portion of the gate region.

### BACKGROUND

Field

The present disclosure relates generally to a metal-oxide-semiconductor field effect transistor (MOSFET) device with split work functions.

Background Art

Advances in semiconductor manufacturing technologies have resulted in dramatically increased circuit packing densities and higher speeds of operation. In order to achieve such increased densities, a wide variety of evolutionary changes have taken place with respect to semiconductor processing techniques and semiconductor device structures over the years.

Many of these process and structural changes have been introduced in connection with device scaling, in which ever smaller device geometries have been achieved. One consequence of conventional field effect transistor (FET) device scaling is a requirement to reduce operating voltages. The reduced operating voltages are required, at least in part, because conventional FET device scaling needs a thinner gate dielectric layer in order to produce the desired electrical characteristics in the scaled-down transistor. Thus, without a reduction in operating voltage, the electric field impressed across the thinner gate dielectric during circuit operation can be high enough for dielectric breakdown, and device failure, to become a problem.

Additionally, as the gate dielectric becomes thinner, gate-induced drain leakage (GIDL) current is becoming a non-negligible source of a transistor's off-state leakage current. Thus, for a conventional FET device, a reduction in operating voltage is required to reduce the off-state leakage caused by GIDL.

However, many integrated circuit designs require both low operating voltage FETs for their ability to operate at high speeds and high operating voltage FETs for their ability to interface with high voltage signals provided by other electronic components.

### BRIEF DESCRIPTION OF THE DRAWINGS/FIGURES

The accompanying drawings, which are incorporated herein and form part of the specification, illustrate the present disclosure and, together with the description, further serve to explain the principles of the disclosure and to enable a person skilled in the relevant art(s) to make and use the disclosure.

FIG. 1A illustrates a cross-sectional view of an n-channel metal oxide semiconductor (NMOS) device, according to an embodiment of the present disclosure.

FIG. 1B illustrates a band diagram of the NMOS device of FIG. 1A, according to an embodiment of the present disclosure.

FIG. 2 illustrates a flow chart illustrating a method of fabricating an NMOS device, according to an embodiment of the present disclosure.

FIGS. 3A-3D illustrate cross-sectional views of partially fabricated NMOS devices, according to an embodiment of the present disclosure.

The present disclosure will now be described with reference to the accompanying drawings. In the drawings, generally, like reference numbers indicate identical or functionally similar elements. Additionally, generally, the left-most digit(s) of a reference number identifies the drawing in which the reference number first appears.

### DETAILED DESCRIPTION

The following detailed description of the present disclosure refers to the accompanying drawings that illustrate exemplary embodiments consistent with this disclosure. Other embodiments are possible, and modifications may be made to the embodiments within the spirit and scope of the disclosure. Therefore, the detailed description is not meant to limit the disclosure.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

It should be understood that relative spatial descriptions between one or more particular features, structures, or characteristics (e.g., “vertically aligned,” “contact,” etc.) used herein are for purposes of illustration only, and that practical implementations of the structures described herein may include fabrication and/or misalignment tolerances without departing from the spirit and scope of the present disclosure.

The example embodiments described herein are provided for illustrative purposes, and are not limiting. Further structural and operational embodiments, including modifications/alterations, will become apparent to persons skilled in the relevant art(s) from the teachings herein.

### Terminology

The terms, chip, die, integrated circuit (IC), semiconductor device, and microelectronic device, are often used interchangeably in the field of electronics.

Polycrystalline silicon is a nonporous form of silicon made up of randomly oriented crystallites or domains. Polycrystalline silicon is often formed by chemical vapor deposition from a silicon source gas or other methods and has a structure that contains large-angle grain boundaries, twin boundaries, or both. Polycrystalline silicon is often referred to in this field as polysilicon, or sometimes more simply as poly. It is noted that polysilicon is commonly used to form the gate electrode of a FET. An alternative use of polysilicon is as a sacrificial “dummy” gate electrode that is removed and replaced with a metal gate during the manufacturing process.

Epitaxial layer refers to a layer of single crystal semiconductor material. In this field, an epitaxial layer is commonly referred to “epi.”

FET, as used herein, refers to a metal-oxide-semiconductor field effect transistor (MOSFET). FETs that are formed in a bulk substrate, such as a silicon wafer, can have four terminals, namely gate, drain, source and body. An n-channel MOSFET (NMOSFET) device, for example, can be fabricated by implanting arsenic atoms into a P-type substrate to form N+ source and drain regions. An NMOSFET device may be interchangeably referred to herein as NMOS device or NMOSFET device. A p-channel MOSFET (PMOSFET) device, for example, can be fabricated by implanting phosphorus atoms into a P-type substrate to create an N-well. P+ regions are formed in the N-well to provide source and drain regions. A PMOSFET device may be interchangeably referred to herein as PMOS device or PMOSFET device.

Effective oxide thickness refers to the thickness of a layer of SiO₂ that is electrically equivalent to a given thickness of a material having a given dielectric constant. In many circumstances it is the electrical characteristic of a dielectric layer (which is proportional to layer thickness/dielectric constant) that is of interest rather than the actual physical thickness of the layer. Historically, the gate dielectric layer was formed almost exclusively from silicon dioxide, but that is no longer the case in the semiconductor industry. Since there are a variety of materials now in use as gate dielectrics, it is easier for the sake of comparison to discuss these gate dielectrics in terms of a normalized value such as effective oxide thickness. By way of example, since HfO₂ has a dielectric constant of 25 (compared to 3.9 for SiO₂), a 6.4 nm layer of HfO₂ has an effective oxide thickness of 1 nm. In other words, a layer of high dielectric constant material can be electrically equivalent to a thinner layer of lower dielectric constant material.

The terms contact and via, both refer to structures in a chip used for electrical connection of conductors from different interconnect levels of the chip. These terms are sometimes used in the art to describe both an opening in an insulator in which the structure will be completed, and the completed structure itself. For purposes of this disclosure, contact and via both refer to the completed structure.

Substrate, as used herein, refers to the physical object that is the basic workpiece transformed by various process operations into the desired microelectronic configuration. A typical substrate used for the manufacture of integrated circuits is in a wafer form, which can be diced after manufacture. Wafers, may be made of semiconducting material (e.g., bulk silicon), non-semiconducting material (e.g., glass), or combinations of semiconducting and non-semiconducting materials (e.g., silicon-on-insulator (SOI)). In the semiconductor industry, a bulk silicon wafer is a very commonly used substrate for the manufacture of integrated circuits.

The term vertical, as used herein, means substantially perpendicular to the surface of a substrate.

An NMOS Device with Split Work Functions According to an Exemplary Embodiment of the Present Disclosure

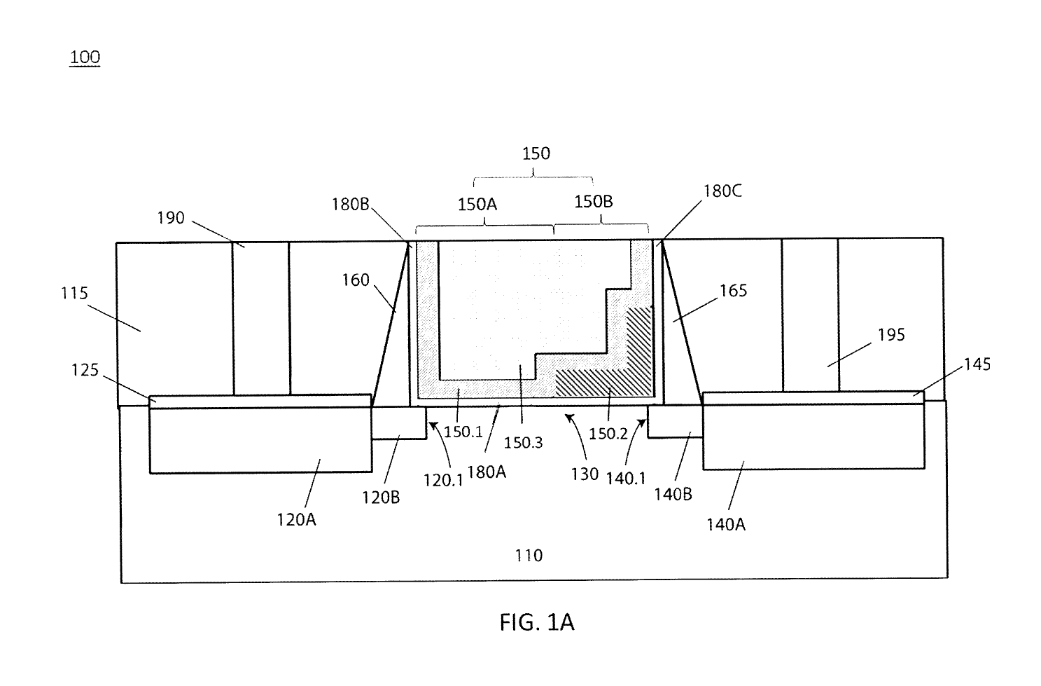

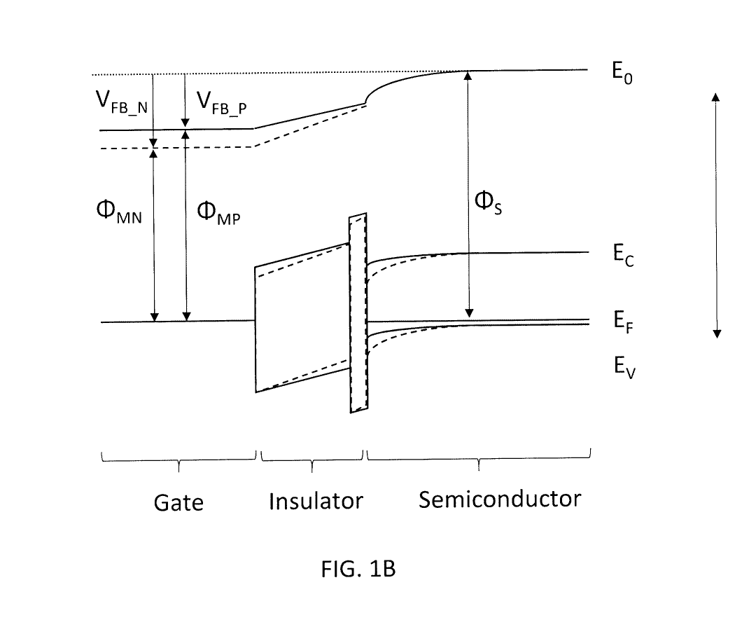

FIG. 1A illustrates a first cross-sectional view of an n-channel metal-oxide-semiconductor (NMOS) device with split work functions, according to a first exemplary embodiment of the present disclosure. An NMOS device 100 is formed onto a substrate 110 of one conductivity type. The substrate 110 represents a physical semiconductor material on which the NMOS device 100 is formed. For example, the NMOS device 100 may be formed in the substrate 110 made of a p-type material. The p-type material includes impurity atoms of an acceptor type that are capable of accepting an electron, such as, but not limited to, boron or aluminum to provide some examples. Alternatively, a fin may be disposed on the substrate 110, and the NMOS device 100 may be formed in the fin.

A first heavily doped region of substantially opposite conductivity as the substrate 110 represents a source region 120 of the NMOS 100. For example, the source region 120 may be implanted with N+ material to form a first N+ region corresponding to the source region 120. The “+” indicates that the region is implanted with a higher carrier concentration than a region not designated by a “+.” For instance, an N+ region generally has a greater number of excess carrier electrons than an n-type region, and a P+ region typically has a greater number of excess carrier holes than a p-type substrate. The n-type material includes impurity atoms of a donor type that are capable of donating an electron, such as, but not limited to, phosphorus, arsenic, or antimony to provide some examples. Generally, implanting a comparatively small number of atoms, approximately 5×10¹⁸ (cm)⁻³ to 1×10¹⁹ (cm)⁻³, refers to an implanting that is low or light. Similarly, implanting a comparatively large number of atoms, approximately 1×10¹⁹ (cm)⁻³ to 5×10²⁰ (cm)⁻³, refers to an implanting that is high or heavy.

The source region 120 may include a first source region 120A and a second source region 120B. The first source region 120A represents the first heavily doped region of substantially opposite conductivity as the substrate 110 while the second source region 120B represents a lightly doped region of substantially opposite conductivity as the substrate 110, also referred to as a lightly-doped source (LDS) region.

A second heavily doped region of substantially opposite conductivity as the substrate 110 represents a drain region 140 of the NMOS device 100. The drain region 140 may include a first drain region 140A and a second drain region 140B. The first drain region 140A represents the first heavily doped region of substantially opposite conductivity as the substrate 110 while the second drain region 140B represents a lightly doped region of substantially opposite conductivity as the substrate 110, also referred to as a lightly-doped drain (LDD) region.

A gate electrode 150 is positioned between the source region 120 and the drain region 140. A first side 120.1 of the source region 120 may extend beyond the source side of the gate electrode 150 by the first substantially horizontal distance such that at least some of the source region 120 is below at least some of the gate electrode 150. Alternatively, the source side of the gate electrode 150 may be substantially vertically aligned with the first side 120.1 of the source region 120 such that no substantial overlap exists between the source region 120 and the gate electrode 150. In another alternative, the first side 120.1 of the source region 120 may be positioned such that none of the source region 120 is below the gate electrode 150. It should be understood that relative spatial descriptions between one or more particular features, structures, or characteristics (e.g., “vertically aligned,” “contact,” etc.) used herein are for purposes of illustration only, and that practical implementations of the structures described herein may include fabrication or misalignment tolerances without departing from the spirit and scope of the present disclosure.

A first side 140.1 of the drain region 140 may extend beyond the drain side of the gate electrode 150 by a second substantially horizontal distance such that at least some of the drain region 140 is below at least some of the gate electrode 150. Alternatively, the drain side of the gate electrode 150 may be substantially vertically aligned with the first side 140.1 of the drain region 140 such that no substantial overlap exists between the drain region 140 and the gate electrode 150. In another alternative, the first side 140.1 of the drain region 140 may be positioned such that none of the drain region 140 is below the gate electrode 150.

A gate dielectric 180 serves as an electrical insulator between the gate electrode 150 and a channel region 130 of the substrate 110 that is between the source region 120 and the drain region 140. The gate dielectric 180 may include a horizontal portion 180A, a first vertical portion 180B, and a second vertical portion 180C. The horizontal portion 180A, the first vertical portion 180B, and the second vertical portion 1800 may be in contact with the gate electrode 150. The horizontal portion 180A is positioned below the gate electrode 150, and the first and second vertical portions 180B, 1800 are positioned adjacent to the gate electrode 150 and/or in contact with the source side and the drain side of the gate electrode 150, respectively. The horizontal portion 180A may have a first uniform thickness, and the first vertical portion 180B and the second vertical portion 180C may have a second uniform thickness. The first uniform thickness and the second uniform thickness may be substantially the same. Alternatively, the first uniform thickness and the second uniform thickness may be different. The first uniform thickness may range between 1.5 nm to 6 nm, and the second uniform thickness may range between 2.5 nm to 6 nm. Other dimensions can be used as will be understood by those skilled in the arts.

The gate dielectric 180 may be formed using a dielectric material such as, but not limited to, silicon dioxide (SiO₂). Gate dielectric 180 may also be formed using a high-k dielectric material such as, but not limited to, hafnium oxide (HfO₂). Alternatively, the gate dielectric 180 may be formed using a plurality of dielectric materials. For example, the gate dielectric 180 may include a layer of hafnium oxide and another layer of silicon dioxide disposed over the layer of hafnium oxide. In such example, the thickness of the silicon dioxide layer may range between 0.5 nm to 4 nm and the thickness of the hafnium oxide layer may range between 1 nm to 2 nm. Gate dielectric 180 may be deposited using physical vapor deposition (PVD), chemical vapor deposition (CVD), atomic layer deposition (ALD), or any other suitable method of deposition. Other dimensions can be used as will be understood by those skilled in the arts.

The gate electrode 150 includes a source-side portion 150A and a drain-side portion 150B, as shown. The source-side portion 150A includes a first gate material 150.1 having a first work function. A work function of a material is defined as the minimum energy required to extract an electron from the surface of the material to free space. The first gate material 150.1 is disposed over and in contact with the horizontal portion 180A of the gate dielectric 180 in the source-side portion 150A of the gate electrode, and disposed over and in contact with the first vertical portion 180B of the gate dielectric 180. Preferably, the first gate material 150.1 has a uniform thickness. The first gate material 150,1 can be an N-type gate material normally used as gate material for an NMOS device. The source-side portion 150A further includes a fill gate material 150.3 disposed over the first gate material 150.1.

The drain-side portion 150B includes a second gate material 150.2 having a second work function that is greater than the first work function of the first gate material 150.1. The second gate material 150.2 is disposed over and in contact with the horizontal portion 180A in the drain-side portion 150B, and disposed over and in contact with the second vertical portion 180C of the gate dielectric 180. Preferably, the second gate material 150.1 has a uniform thickness. The second gate material 150.2 can be a P-type gate material normally used as gate material for a PMOS device. The drain-side portion 150B further includes the first gate material 150.1 disposed over the second gate material 150.2, as shown. The drain-side portion 150B further includes the fill gate material 150.3 disposed over and in contact with the first gate material 150.1, which is disposed over and in contact with the second gate material 150.2.

Accordingly, the gate electrode 150 for the NMOS 100 is constructed with two types of gate material (or 3 types including the fill material). Namely, the source-side portion 150A includes N-type gate material 150.1 disposed on the gate dielectric 180A. Whereas, the drain-side portion 150B includes the P-type gate material 150.2 disposed on the gate dielectric 180A and the N-type gate material 150.1 disposed on, and in contact with, the P-type gate material 150.2 as shown. Finally, the fill gate material 150.3 is disposed on the N-type gate material 150.1 on both the source-side portion 150A and the drain-side portion 150B, so as to “fill” the gate electrode 150 with a low-resistance gate material. As will be shown, the disparate use of gate materials between the source-side portion 150A and the drain-side portion 150B causes the work function of the drain-side portion 150B to be different than that of the source-side portion 150A.

The first gate material 150.1 may be, for example, an aluminum alloy (e.g., titanium aluminum) with a work function ranging from 4.05 eV to 4.61 eV or element aluminum with a work function about 4.08 eV, and that is used for NMOS gate metal. The second gate material may also be metal. For example, the second gate material may be titanium nitride with a work function of about 4.7 eV. The second gate material may be the gate material used to form a PMOS device gate electrode in the same substrate. The fill gate material may be a low resistance metal. For example, the fill gate material may be tungsten. The first gate material may have thicknesses ranging from 4 nm to 20 nm. The second gate material may have a thickness ranging from 4 nm to 20 nm. The gate electrode 150 may have a thickness ranging from 300 nm to 600 nm. Other dimensions can be used as will be understood by those skilled in the arts.

FIG. 1B illustrates a band diagram of the gate electrode 150. Solid lines represent the drain-side portion 150B and dashed lines represent the source-side portion 150A. As discussed above, the first work function Φ_{MN} of the source-side portion 150A is less than the second work function Φ_{MP} of the drain-side portion 150B. Thus, the flat-band voltage V_{FB}_{_}_{N} of the source-side portion 150A is also lower than the flat-band voltage V_{FB}_{_}_{P} of the drain-side portion 150B. A flat-band voltage, which is often a negative voltage, is defined as the difference between the work function of a gate material and the work function of the semiconductor Φ_{S}, and it is the voltage that needs to be applied between a gate electrode and a source region to create a flat-band condition. In other words, in an equilibrium or when a positive voltage is applied between the gate electrode 150A and the source region 120 (for NMOS), a stronger electric field exists in the horizontal portion 180A that overlaps with the source-side portion 150A compared to the horizontal portion 180A that overlaps with the drain-side portion 150B.

Still referring to FIG. 1A, the NMOS device 100 may include a spacer 160 above the source region 120 and/or adjacent to the gate electrode 150 to isolate and/or protect the source region 120 and the gate electrode 150 and a spacer 165 above the drain region 140 and/or adjacent to the gate electrode 150 to isolate and/or protect the drain region 140 and the gate electrode 150. More specifically, the NMOS device 100 may include a spacer 160 above the source region 120 and/or adjacent to the first vertical portion 180B of the gate dielectric 180 to isolate and/or protect the source region 120 and the gate electrode 150, and a spacer 165 above the drain region 140 and/or adjacent to the second vertical portion 1800 of the gate dielectric 180 to isolate and/or protect the drain region 140 and the gate electrode 150. The spacer 160 and/or the spacer 165 may be formed using a dielectric material, such as SiₓNₓ or SiO₂, though any suitable material may be used.

The NMOS device 100 may further include an epi-source region 125 above the source region 120 and an epi-drain region 145 above the drain region 140. The NMOS device 100 may further include a source contact 190 above and/or in contact with the epi-source region 125 and a drain contact 195 above and/or in contact with the epi-drain region 145. The NMOS device 100 may further include an inter-layer dielectric (ILD) 115 above the substrate 110. The ILD 115 serves as an electrically insulating layer for the source contact 190 and the drain contact 195.

A p-n junction is a potential barrier created by combining the n-type and the p-type material. A first interface between the substrate 110 and the source region 120 may represent a first p-n junction. Likewise, a second interface between the substrate 110 and the drain region 140 may represent a second p-n junction. The first p-n junction and/or the second p-n junction may prevent current conduction from the source region 120 to the drain region 140 upon the application of a voltage between the source region 120 to the drain region 140. On the other hand, applying a first potential, such as a first positive direct current (DC) voltage to provide an example, to the gate electrode 150 and a second potential, such as a ground potential to provide an example, to the source region 120 may cause a voltage to appear between the gate electrode 150 and the source region 120. When this voltage is greater than a first threshold voltage of the NMOS device 100, the first potential on the gate electrode 150 repels the positively charged carrier holes below the gate electrode 150 to form a channel in the channel region 130.

The channel in the channel region 130 represents a carrier-depletion region populated by a negative charge formed below the horizontal portion 180A of the gate dielectric 180 by an electric field. The electric field attracts carrier electrons from the source region 120 and the drain region 140 into the channel region 130. An n-type region connecting the source region 120 to the drain region 140 forms after a sufficient number of the carrier electrons accumulate in the channel region allowing current to flow between the source region 120 to the drain region 140.

However, the amount of voltage applied between the gate electrode 150 and the source region 120 and between the drain region 140 and the source region 120 have limits. When the voltage across the thickness of the gate dielectric 180 exceeds the breakdown voltage associated with the dielectric material, the gate dielectric 180 breaks down. Gate dielectric breakdown, also known as dielectric rupture or dielectric punch-through, causes destruction of the gate dielectric 180. The gate dielectric breakdown results from a build-up of defects inside the gate dielectric 180 which eventually leads to a creation of a conductive path in the gate dielectric 180 from the gate electrode 150 to the channel in the channel region 130. For example, a hot carrier effect may cause the defects inside the gate dielectric 180. The hot carrier effect refers to an effect of high energy carrier electrons and/or carrier holes generated as a result of impact ionization at the channel region. These high energy current carriers may leave the substrate 110 and may, upon reaching a sufficiently high level of energy, tunnel into the gate dielectric 180 to cause the defects.

Gate dielectric breakdown may occur as a result of a lateral electric field caused by the voltage applied between the source region 120 and the drain region 140 and as a result of a vertical electrical field caused by the voltage applied between the gate electrode 150 and the source region 120.

The vertical electric field intensity at the horizontal portion 180A of the gate dielectric 180 can be expressed as E=Vₒₓ/d, where the Vₒₓ represents the voltage across a thickness of the horizontal portion 180A and d represents the thickness of the horizontal portion 180A. Furthermore, Vₒₓ may be expressed as Vₒₓ=V_{g}−V_{fb}−Vₛᵢ, where V_{g} is voltage applied between the gate electrode 150 and the source region 120, V_{fb} is the flat-band voltage of the gate electrode 150, and Vₛᵢ is the semiconductor surface potential. Thus, for a conventional NMOS device with a homogeneous gate electrode, the flat band voltage is uniform across the interface between the gate electrode and the gate dielectric, and the Vₒₓ is also uniform across the same interface. However, due to a peak lateral electric field that typically occurs near a drain region, a gate dielectric of the conventional NMOS device typically breaks_down near the drain region first.

NMOS device 100, however, has a non-homogeneous gate electrode 150; the gate electrode 150 includes the source-side portion 150A and the drain-side portion 15013. As discussed above and as illustrated in FIG. 1B, the first work function Φ_{MN} of the source-side portion 150A is less than the second work function Φ_{MP} of the drain-side portion 150B, and the flat-band voltage V_{FB}_{_}_{N} of the source-side portion 150A is lower than the flat-band voltage V_{FB}_{_}_{P} of the drain-side portion 150B. Thus, the horizontal portion 180A of the gate dielectric 180 below the drain-side portion 150B has a lower Vₒₓ when compared to the horizontal portion 180A of the gate dielectric 180 below the source-side portion 150A because Vₒₓ and a flat-band voltage are inversely correlated. Accordingly, the electric field intensity at the drain-side portion 150B is reduced relative to the source-side portion 150A, for a given gate-to-source voltage.

The reduced electric field intensity near the drain region 140 may compensate for the peak lateral electric field that typically occurs near a drain region and may enable an operating voltage of the NMOS device 100 to be higher than an operating voltage of the conventional NMOS device. Additionally, the reduction in the total electrical field intensity near the drain region reduces the degree of band bending in the region where the drain region and the gate electrode overlap. Thus, gate-induced drain leakage (GIDL) current may also be reduced.

Exemplary Processes

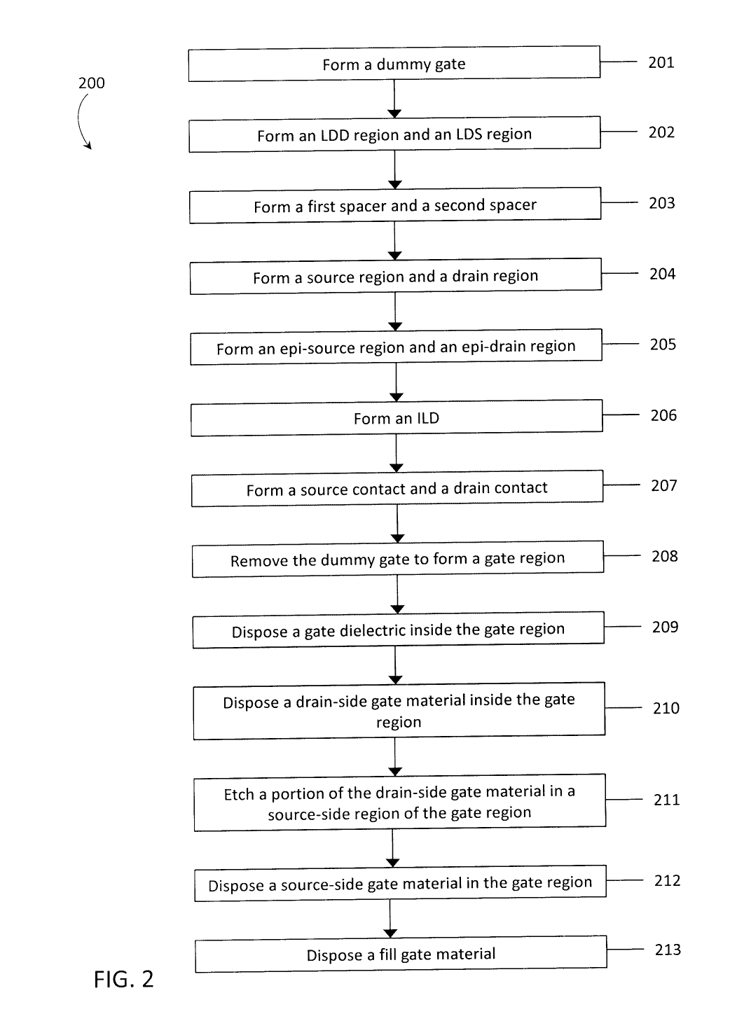

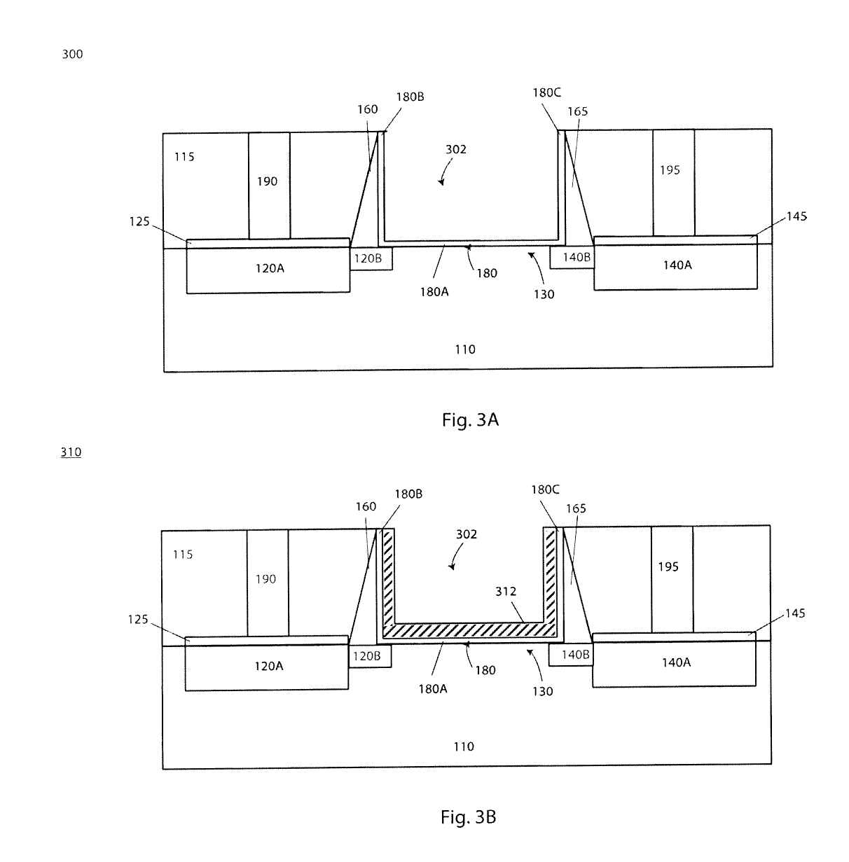

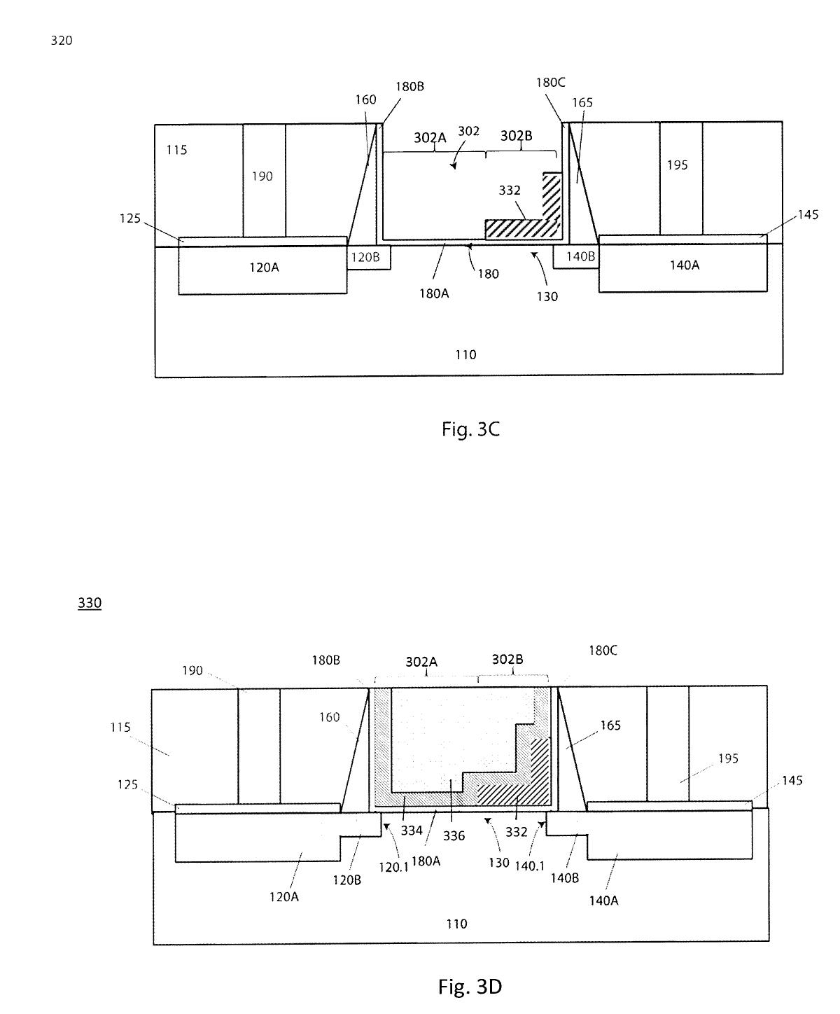

FIG. 2 is a flow diagram of an exemplary process 200 for fabricating the NMOS device 100 of FIG. 1A. Process 200 will be described in references to FIGS. 3A-3D to illustrate the device fabrication for the various process steps.

Referring to FIG. 3A for steps 201-209, at step 201, a polycrystalline silicon dummy gate is formed on a p-type substrate 110. At step 202, an LDD region 120A and an LDS region 120B are formed in the substrate 110. At step 203, a first spacer 160 and a second spacer 165 are formed adjacent to the dummy gate on the substrate 110. At step 204, a source region 120A and a drain region 140A are formed in the substrate. At step 205, an epi-source region 125 and an epi-drain region 145 are formed above the source and drain regions 120A, 140A. At a step 206, an ILD 115 is formed over the entire substrate. At step 207, a source contact 190 and a drain contact 195 are formed above the epi-source region 125 and the epi-drain region 145, respectively. At step 208, the dummy gate is removed to form a gate region 302. At step 209, a gate dielectric 180 is formed inside the gate region 302.

Referring to FIG. 3B for step 210, a drain-side gate material 312 is disposed inside the gate region 302 over the gate dielectric 180.

Referring to FIG. 3C for step 211, a portion of the drain-side gate material 312 in a source side region 302A of the gate region 302 is etched such that a remaining drain-side gate material 332 is in the drain-side region 302B of the gate region 302.

Referring to FIG. 3D for steps 212-213, at step 212, a source-side gate material 334 is disposed in the source-side region 302A and the drain-side region 302B of the gate region 302 and over the remaining drain-side gate material 332. At step 213, a fill gate material 334 is disposed in the source-side region 302A and the drain-side region 302 of the gate region 302 and over the source-side gate material 334.

### Conclusion

The exemplary embodiments described herein are provided for illustrative purposes, and are not limiting. Other exemplary embodiments are possible, and modifications may be made to the exemplary embodiments within the spirit and scope of the disclosure.

It is to be appreciated that the Detailed Description section, and not the Abstract section, is intended to be used to interpret the claims. The Abstract section may set forth one or more, but not all exemplary embodiments, of the disclosure, and thus, are not intended to limit the disclosure and the appended claims in any way.

The disclosure has been described above with the aid of functional building blocks illustrating the implementation of specified functions and relationships thereof. The boundaries of these functional building blocks have been arbitrarily defined herein for the convenience of the description. Alternate boundaries may be defined so long as the specified functions and relationships thereof are appropriately performed.

It will be apparent to those skilled in the relevant art(s) that various changes in form and detail can be made therein without departing from the spirit and scope of the disclosure. Thus the disclosure should not be limited by any of the above-described exemplary embodiments. Further, the claims should be defined only in accordance with their recitations and their equivalents.

What is claimed is:

1. A transistor, comprising:
a source region;
a drain region;
a channel region formed between the source region and the drain region;
a gate electrode having a source-side portion and a drain-side portion, wherein a first work function of the source-side portion is less than a second work function of the drain-side portion; and
a gate dielectric layer comprising a horizontal portion, wherein the horizontal portion is disposed between the gate electrode and the channel region.

2. The transistor of claim 1, wherein the source region comprises a heavily doped source region and a lightly-doped source (LDS) region and the LDS region is formed between the heavily doped source region and the channel region, and
wherein the drain region comprises a heavily doped drain region and a lightly-doped drain (LDD) region and the LDD region is formed between the heavily doped drain region and the channel region.

3. The transistor of claim 2, further comprising:
a source-side spacer and a drain-side spacer;
wherein the gate dielectric layer further comprises a first vertical portion interposed between the source-side spacer and the gate electrode and a second vertical portion interposed between the drain-side spacer and the gate electrode.

4. The transistor of claim 1, wherein the source-side portion and the drain-side portion of the gate electrode are in contact with the horizontal portion of the gate dielectric layer.

5. The transistor of claim 4, wherein the source-side portion of the gate electrode comprises a first gate material disposed over the horizontal portion of the gate dielectric, and wherein the drain-side portion of the gate electrode comprises a second gate material disposed over the horizontal portion of the gate dielectric and the first gate material disposed over the second gate material.

6. The transistor of claim 5, wherein the gate electrode further comprises a fill gate material disposed over the first gate material in the source-side portion and the drain-side portion of the gate electrode.

7. The transistor of claim 5, wherein the combination of the first gate material disposed over the second gate material in the drain-side portion causes the second work function to be greater than the first work function.

8. The transistor of claim 5, wherein the first gate material is a gate metal associated with an n-type metal oxide semiconductor (moos) device, and wherein the second gate material is a gate metal associated with a p-type metal oxide semiconductor (PMOS) device.

9. The transistor of claim 5, wherein the first gate material is aluminum or titanium aluminum, and wherein the second gate material is a titanium nitride based metal.

10. The transistor of claim 1, further comprising a substrate, wherein the source region, the drain region, and the channel region are formed in the substrate.

11. The transistor of claim 11, wherein the substrate is a p-type semiconductor, and the source and drain regions are doped with n-type dopants.

12. A transistor, comprising:
a source region;
a drain region;
a channel region laterally formed between the source region and the drain region; and
a gate region configured to control a conductivity of the channel region, the gate region including a gate dielectric disposed on the channel region and a gate electrode disposed on the gate dielectric, wherein the gate electrode includes:
a source-side portion disposed laterally proximate to the source region, the source-side portion including a layer of n-type gate metal disposed on the gate dielectric, and
a drain-side portion disposed laterally proximate to the drain region, the drain-side portion including a first layer of p-type gate metal disposed on the gate dielectric and a second layer of the n-type gate metal disposed on the first layer of p-type gate metal.

13. The transistor of claim 12, wherein the source-side portion of the gate electrode is characterized by a first work function, and the drain-side portion of the gate electrode is characterized by a second work function that is greater than the first work function.

14. The transistor of claim 12, wherein the n-type gate metal is a gate metal associated with fabrication of an n-type metal oxide semiconductor (NMOS) device, and the p-type gate metal is a gate metal associated with fabrication of a p-type metal oxide semiconductor (PMOS) device.

15. The transistor of claim 14, wherein the n-type gate metal is aluminum or titanium aluminum, and wherein the p-type gate metal is a titanium nitride based metal.

16. The transistor of claim 12, wherein the gate electrode further comprises a gate fill metal disposed over the n-type gate metal in the source-side portion and the drain-side portion so that a top surface of the gate electrode is substantially level with corresponding top surfaces of a source contact of the source region and a drain contact of the drain region.

17. The transistor of claim 12, further comprising a substrate, wherein the source region, the drain region, and the channel region are formed in the substrate.

18. The transistor of claim 17, wherein the substrate is a p-type semiconductor, and the source and drain regions are doped with n-type dopants.

19. A method of fabricating a transistor, comprising:
forming a dummy gate;
forming a source region and a drain region;
removing the dummy gate to form a gate region;
disposing a gate dielectric in the gate region; and
forming a gate electrode over the gate dielectric, including
disposing a drain-side gate material in the gate region,
etching a portion of the drain-side gate material in a source-side portion of the gate region to remove the drain-side gate material from the source-side portion of the gate region, and
disposing a source-side gate material over the gate dielectric in the source-side portion of the gate region and over a drain-side gate material in a drain-side portion of the gate region.

20. The method of claim 19, wherein forming the gate electrode further comprises disposing a gate fill material over the source-side gate material and the drain-side gate material.
